(19) United States
(12) Patent Application Publication
(10) Pub. No.: US 2025/0125195 A1
(43) Pub. Date: Apr. 17, 2025

(54) OLIGOMER FILM FOR BOTTOM-UP GAP FILL PROCESSES

(71) Applicant: Applied Materials, Inc., Santa Clara, CA (US)

(72) Inventors: Feng Q. Liu, San Jose, CA (US); Xinke Wang, Singapore (SG); Liqi Wu, San Jose, CA (US); Qihao Zhu, Sunnyvale, CA (US); Mark Saly, Santa Clara, CA (US); Jiang Lu, Milpitas, CA (US); John Sudijono, Singapore (SG); David Thompson, San Jose, CA (US)

(73) Assignee: Applied Materials, Inc., Santa Clara, CA (US)

(21) Appl. No.: 18/378,828

(22) Filed: Oct. 11, 2023

(51) Int. Cl. H01L 21/768; H01L 21/02

(52) U.S. Cl. CPC H01L 21/76831; H01L 21/02118; H01L 21/76879

(57) ABSTRACT

Embodiments of the disclosure relate to methods using an oligomer film to protect a substrate surface. The oligomer film is formed on the substrate surface with a first feature and a second feature each having a feature depth. The first feature has a first critical dimension (CD) and the second feature has a second CD. The semiconductor substrate surface is exposed to one or more monomers to form the oligomer film, and the oligomer film forms selectively on the bottom and fills a portion of the feature depth. The oligomer film fills the feature depth to substantially the same or the same height in each of the first feature and the second feature. Methods of forming semiconductor devices using the oligomer film are also disclosed.

### TECHNICAL FIELD

Embodiments of the present disclosure pertain to selective deposition processes. More particularly, one or more embodiments are directed to selective metal deposition processes to fill a feature, e.g., a trench, after use of a flowable oligomer film to protect a bottom surface within the feature.

### BACKGROUND

Gap fill processes are integral to several semiconductor manufacturing techniques. A gap fill process can be used to fill a gap (e.g., a feature) with an insulating or conductive material. For example, shallow trench isolation, inter-metal dielectric layers, passivation layers, and dummy gate, among several other applications, are all typically implemented by gap fill processes.

As device geometries continue to shrink (e.g., critical dimensions <20 nm, <10 nm, and beyond) and thermal budgets are reduced, defect-free filling of gaps becomes increasingly difficult due to the limitations of conventional deposition processes.

Processes for selective metal gap fill, such as tungsten fill, have been implemented where tungsten can be selectively deposited on a tungsten seed layer (e.g., a tungsten liner layer). Unfortunately, these processes require a minimum seed layer thickness. Known physical vapor deposition (PVD) processes can provide the necessary seed layer thickness, but the tungsten fill process will deposit tungsten material on any exposed seed layer and therefore has poor selectivity. Additionally, there are no known selective metal deposition methods on metal or metal silicide without causing damage to the underlying metal or metal silicide.

Processes for selective deposition of a polymer film to achieve selective protection of a semiconductor substrate surface have been explored. However, it has been found that the height of the polymer film varies with varying critical dimensions (CD) of the feature in which the polymer film is formed. As such, the effectiveness of depositing a polymer film with uniform or substantially uniform height is dependent on the CD of the feature.

Accordingly, there is a need for methods to selectively protect semiconductor substrate surfaces without dependence on the CD of the feature.

### SUMMARY

One or more embodiments of the disclosure are directed to a processing method. In one or more embodiments, the processing method comprises: exposing a semiconductor substrate surface with at least one feature formed thereon to one or more monomers to form an oligomer film. The at least one feature has at least one opening having a width, at least one sidewall, and a bottom, and extends a feature depth from a top surface to the bottom. The oligomer film forms selectively on the bottom and fills a portion of the feature depth.

Additional embodiments of the disclosure are directed to a processing method. In one or more embodiments, the processing method comprises: exposing a semiconductor substrate surface with a first feature and a second feature formed thereon to one or more monomers to form an oligomer film. Each of the first feature and the second feature have at least one opening having a width, at least one sidewall, and a bottom, and extend a feature depth from a top surface to the bottom. The first feature has a first critical dimension (CD) and the second feature has a second CD, and the second CD is greater than the first CD. The oligomer film forms selectively on the bottom and fills a portion of the feature depth.

Further embodiments of the disclosure are directed to a method of forming a semiconductor device. In one or more embodiments, the method comprises: depositing a first metal layer on a substrate surface with a first feature and a second feature formed thereon. Each of the first feature and the second feature include at least one opening, at least one sidewall, and a bottom, and extend a feature depth from a top surface to the bottom. The first feature has a first critical dimension (CD) and the second feature has a second CD, and the second CD is greater than the first CD. The first metal layer forms on the top surface, on the at least one sidewall, and on the bottom. In one or more embodiments, the method further comprises exposing the substrate surface to one or more monomers to form an oligomer film on the first metal layer within the first feature and the second feature. The oligomer film forms on the first metal layer on the bottom and on a portion of the at least one sidewall, and the oligomer film fills the feature depth to substantially the same height in each of the first feature and the second feature. In one or more embodiments, the method further comprises: selectively removing the first metal layer from the top surface and from the at least one sidewall; removing the oligomer film to expose the first metal layer on the bottom of the first feature and the second feature; and selectively depositing a second metal layer on the first metal layer to fill each of the first feature and the second feature.

### BRIEF DESCRIPTION OF THE DRAWINGS

So that the above recited features of the present disclosure can be understood in detail, a more particular description of the disclosure, briefly summarized above, may be had by reference to embodiments, some of which are illustrated in the appended drawings. It is to be noted, however, that the appended drawings illustrate one or more embodiments of this disclosure and are therefore not to be considered limiting of its scope, for the disclosure may admit to other equally effective embodiments.

FIG. 1 illustrates a process flow diagram of a method of forming a semiconductor device according to one or more embodiments;

FIG. 2 illustrates a cross-sectional view of a semiconductor substrate having at least one feature according to one or more embodiments;

FIG. 3 illustrates a cross-sectional view of the semiconductor substrate of FIG. 2 after deposition of a first metal layer;

FIG. 4 illustrates a cross-sectional view of the semiconductor substrate of FIG. 3 after forming an oligomer film;

FIG. 5A illustrates a cross-sectional view of the semiconductor substrate of FIG. 4 after removal of a portion of the first metal layer;

FIG. 5B illustrates an exploded view of a semiconductor substrate in cross-section according to the prior art;

FIG. 5C illustrates an exploded view of the semiconductor substrate showing the oligomer film according to one or more embodiments;

FIG. 6 illustrates a cross-sectional view of the semiconductor substrate of FIG. 5C after removal of the oligomer film;

FIG. 7 illustrates a cross-sectional view of the semiconductor substrate of FIG. 6 after selectively depositing a second metal layer on the first metal layer to fill the at least one feature; and

FIG. 8 is a schematic top-view diagram of an example multi-chamber processing system according to one or more embodiments.

To facilitate understanding, identical reference numerals have been used, unless indicated otherwise to designate identical elements that are common to the Figures. It is contemplated that elements of one embodiment may be beneficially incorporated in other embodiments without further recitation.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

The term “about” as used herein means approximately or nearly and in the context of a numerical value or range set forth means a variation of ±15% or less, of the numerical value. For example, a value differing by ±14%, ±10%, ±5%, ±2%, ±1%, ±0.5%, or ±0.1% would satisfy the definition of about.

Spatially relative terms, such as “beneath,” “below,” “lower,” “above,” “upper” and the like, may be used herein for ease of description to describe one element's relationship to another element(s) or as illustrated in the Figures. It will be understood that the spatially relative terms are intended to encompass different orientations of a device, such as a semiconductor device, in use or operation in addition to the orientation depicted in the Figures. For example, if the device in the Figures is turned over, elements described as “below,” or “beneath” other elements or features would then be oriented “above” the other elements or features. Thus, the exemplary term “below” may encompass both an orientation of above and below. The device may be otherwise oriented (rotated 90 degrees or at other orientations) and the spatially relative descriptors used herein interpreted accordingly.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

Reference throughout this specification to “one embodiment,” “certain embodiments,” “one or more embodiments,” “some embodiments,” or “an embodiment” means that a particular element, structure, material, or characteristic described in connection with the embodiment is included in at least one embodiment of the disclosure. Thus, the instances in which the phrases such as “in one or more embodiments,” “in certain embodiments,” “in one embodiment,” “in some embodiments,” or “in an embodiment” used in various places throughout this specification are not necessarily referring to the same embodiment of the disclosure. In one or more embodiments, the particular elements, structures, materials, or characteristics are combined in any suitable manner.

As used in this specification and the appended claims, the term “substrate” or “wafer” refers to a surface, or portion of a surface, upon which a process acts. It will also be understood by those skilled in the art that reference to a substrate can refer to only a portion of the substrate unless the context clearly indicates otherwise. Additionally, reference to depositing on a substrate can mean both a bare substrate and a substrate with one or more films or features deposited or formed thereon.

A “substrate” as used herein, refers to any substrate or material surface formed on a substrate upon which layer or film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal and/or bake the substrate surface. In addition to film processing directly on the surface of the substrate itself, in the present disclosure, any of the film processing steps disclosed may also be performed on an under-layer formed on the substrate as disclosed in more detail below, and the term “substrate surface” is intended to include such under-layer as the context indicates. Thus, for example, where a film/layer or partial film/layer has been deposited onto a substrate surface, the exposed surface of the newly deposited film/layer becomes the substrate surface.

The substrate surface may have one or more features formed therein, thereon, one or more layers formed thereon, and combinations thereof. The shape of the feature can be any suitable shape including, but not limited to, trenches, holes and vias (circular or polygonal). As used in this regard, the term “feature” refers to any intentional surface irregularity. Suitable examples of features include but are not limited to trenches, which have a top, two sidewalls and a bottom extending into the substrate, vias which have one or more sidewall extending into the substrate to a bottom, and slot vias. The features described herein can have any suitable aspect ratio (ratio of the depth of the feature to the width of the feature). In one or more embodiments, the aspect ratio of the features described herein is greater than or equal to about 1:1, 2:1, 5:1, 10:1, 15:1, 20:1, 25:1, 30:1, 35:1, or 40:1.

Chemical vapor deposition (CVD) is one of the most common deposition techniques employed, and the process flow of a typical CVD technique will be understood by the skilled artisan. A variant of CVD that demonstrates excellent step coverage is “cyclical deposition” or “atomic layer deposition (ALD).” ALD employs chemisorption techniques to deliver precursor molecules on a substrate surface in sequential cycles. For example, an ALD cycle may include exposing the substrate surface to a first precursor, a purge gas, a second precursor, and the purge gas. The first and second precursors react to form a product compound as a film on the substrate surface. The ALD cycle is repeated to form the layer to a desired thickness.

As used in this specification and the appended claims, the term “selectively” refers to a process which acts on a first surface with a greater effect than another second surface. Such a process would be described as acting “selectively” on the first surface over the second surface. The term “over” used in this regard does not imply a physical orientation of one surface on top of another surface, rather a relationship of the thermodynamic or kinetic properties of the chemical reaction with one surface “relative to” the other surface.

As used in this specification and the appended claims, “selective” deposition of materials can be accomplished in a variety of ways. For instance, some processes may have inherent selectivity to surfaces based on their surface chemistry. A chemical precursor may react selectively with one surface relative to another surface (metallic or dielectric). Process parameters such as pressure, substrate temperature, precursor partial pressures, and/or gas flows may be modulated to modulate the chemical kinetics of a particular surface reaction.

The term “on” indicates that there is direct contact between elements. The term “directly on” indicates that there is direct contact between elements with no intervening elements.

As used in this specification and the appended claims, the terms “precursor,” “reactant,” “reactive gas” and the like are used interchangeably to refer to any gaseous species that can react with the substrate surface.

Embodiments of the disclosure advantageously provide methods for selectively depositing a metal after use of a flowable oligomer film to protect a bottom surface within a feature. One or more embodiments advantageously provide for the removal of a metallic material from the field (e.g., a top surface of a feature) and sidewalls of a feature without removal of the oligomer film from the bottom surface of the semiconductor substrate.

One or more embodiments advantageously provide methods for depositing an oligomer film that has a height which is substantially the same or the same in features with varying critical dimensions (CD). Further embodiments advantageously provide methods for selectively depositing a metallic gap fill material without seams or voids in a bottom-up fashion.

The embodiments of the disclosure are described by way of the Figures, which illustrate a method, semiconductor substrates during stages of manufacture, and a multi-chamber processing system. The method, the multi-chamber processing system, and resulting semiconductor substrates shown are merely illustrative of the disclosed processes, and the skilled artisan will recognize that the disclosed processes are not limited to the illustrated applications.

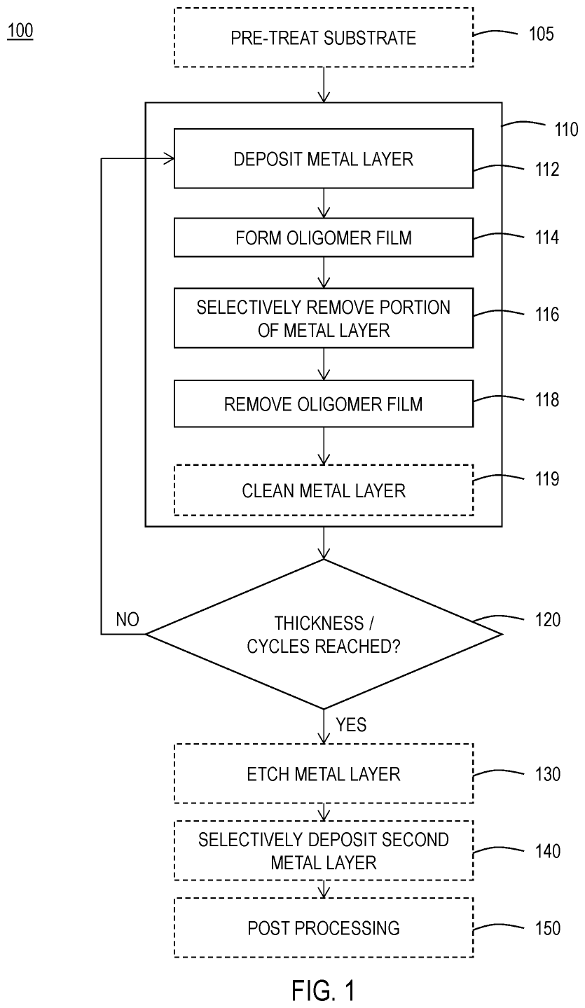

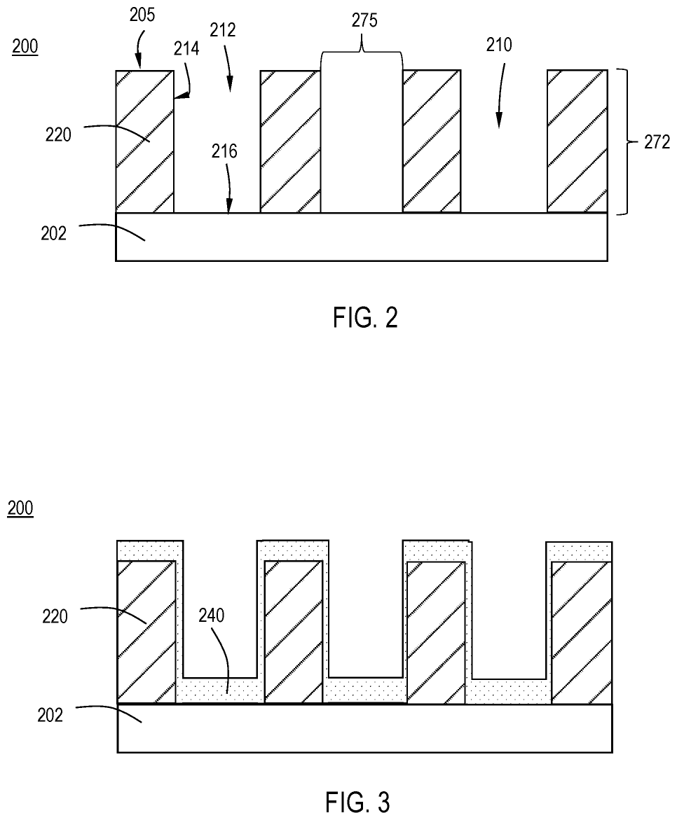

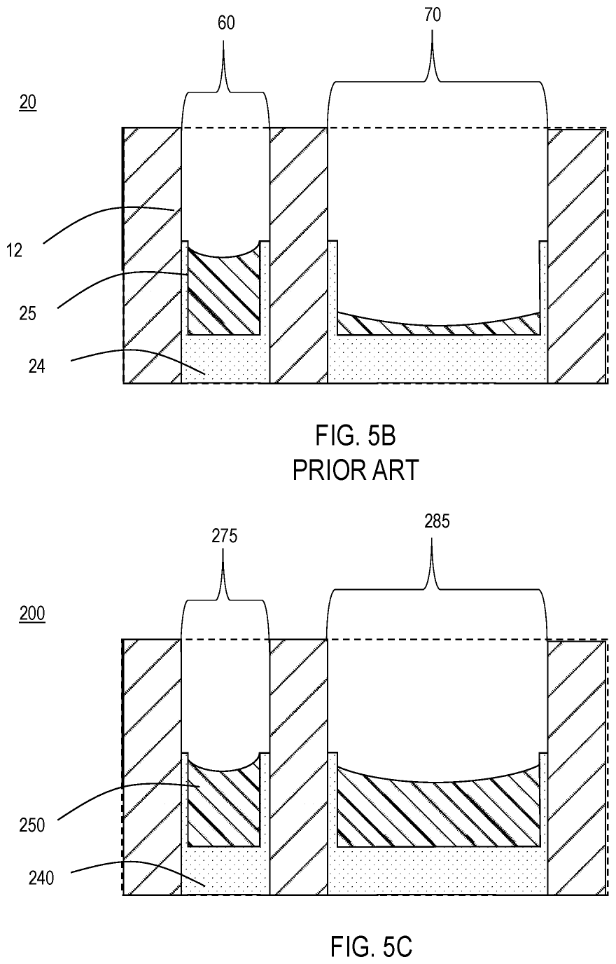

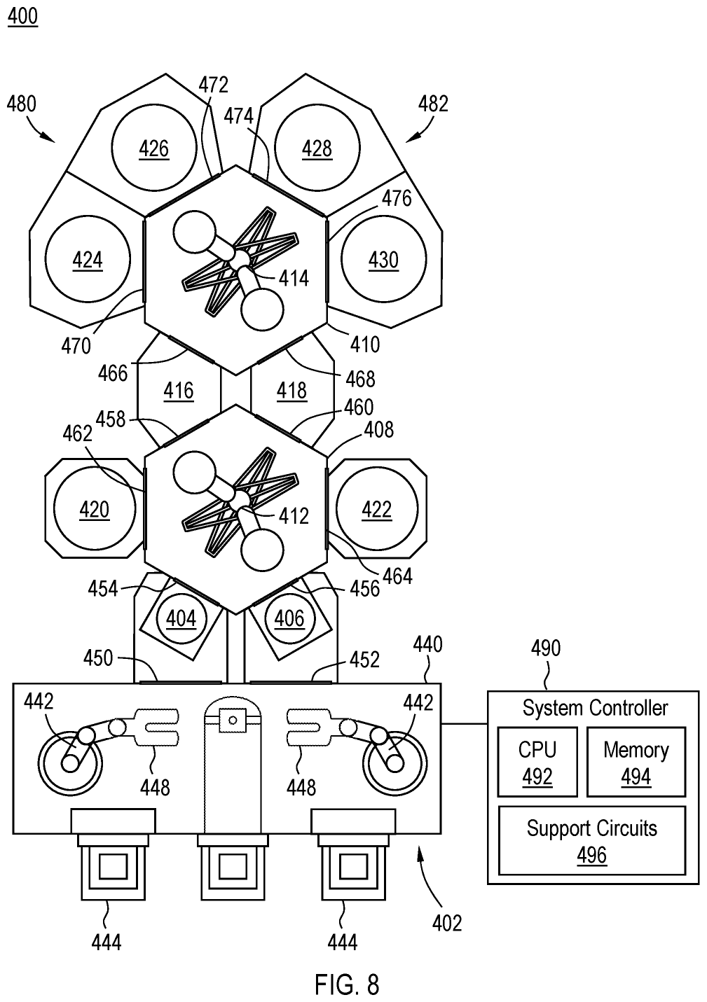

FIG. 1 illustrates a process flow diagram of a method 100 of forming a semiconductor device 200 in accordance with one or more embodiments. FIGS. 2-5A and 5C-7 illustrate the semiconductor device 200 having a semiconductor substrate surface 202 with at least one feature 210 formed thereon during stages of manufacture. In some embodiments, the method 100 forms the semiconductor device 200 of FIGS. 2-5A and 5C-7. FIG. 5B illustrates an exploded view of a semiconductor substrate in cross-section according to the prior art. FIG. 8 is a schematic top-view diagram of the multi-chamber processing system, e.g., processing system 400, in which the methods disclosed herein, e.g., method 100, may be performed.

FIG. 2 illustrates a semiconductor device 200 with a semiconductor substrate surface 202. The terms “semiconductor substrate surface 202” and “substrate surface 202” may be used interchangeably. As identified above, the substrate surface 202 refers to the exposed surface of the substrate upon which a process may be performed. The substrate surface 202 has at least one feature 210 formed thereon. While only three features are shown in the Figures, one skilled in the art will recognize that any suitable number of features will each be affected by the disclosed methods in a similar manner.

The at least one feature 210 has an opening 212 with an opening width 275. The opening 212 is defined by one or more sidewalls 214 and extends a feature depth 272 from the top surface 205 to the bottom 216. While straight, vertical sidewalls 214 are shown in the Figures, the disclosed methods may also be performed on slanted, irregular, reentrant sidewalls, including, but not limited to, features having one or more overhangs and/or undercuts.

In one or more embodiments, the semiconductor device 200 illustrated in FIG. 2 includes a material 220 on the substrate surface 202. In one or more embodiments, the material 220 includes a dielectric material. The dielectric material can be any suitable dielectric material known to the skilled artisan. Those skilled in the art will recognize that the field (e.g., top surface 205), sidewall 214, and bottom 216 may each include one or more similar or different materials. For example, the lower portion of sidewall 214 may be formed from a first material while the upper portion of the same sidewall 214 may be comprised of a second material. Similarly, a thin layer may be deposited on the top surface 205 without forming an appreciable portion of the sidewall 214. In one or more embodiments, the bottom 216 may include a different material than the sidewall 214. In one or more embodiments, the bottom 216 comprises the material of the substrate surface 202.

In one or more embodiments, the substrate surface 202 comprises a conductive material, such as a metallic material, and the material 220 comprises a dielectric material. Those skilled in the art will recognize that the disclosed processes may be performed on different materials and/or that the illustrated structures may be arranged in different ways.

In one or more embodiments, the opening width 275 of the opening 212 is less than or equal to about 60 nm, less than or equal to about 50 nm, less than or equal to about 30 nm, less than or equal to about 20 nm, less than or equal to about 10 nm, less than or equal to about 7 nm, or less than or equal to about 6 nm. In one or more embodiments, the opening width 275 refers to the critical dimension (CD) of the at least one feature 210. While the opening width 275 is shown to be the same in each of the features 210 in FIGS. 2-4, one skilled in the art will recognize that features 210 do not necessarily have the same opening width. In one or more embodiments, the opening width 275 is in a range of about 6 nm to about 20 nm. As will be described further below, one or more of the at least one features 210 may have varying opening widths (varying CD).

In one or more embodiments, the feature depth 272 of the feature 210 is greater than or equal to about 5 nm, greater than or equal to about 10 nm, greater than or equal to about 20 nm, greater than or equal to about 50 nm, greater than or equal to about 60 nm, greater than or equal to about 75 nm, greater than or equal to about 100 nm, greater than or equal to about 200 nm, greater than or equal to about 300 nm, greater than or equal to about 400 nm, or greater than or equal to about 450 nm. In one or more embodiments, the feature depth 272 is in a range of about 5 nm to about 500 nm. In one or more embodiments, the aspect ratio of the at least one feature 210 is greater than or equal to about 5:1, 10:1, 15:1, 20:1, 25:1, 30:1, 35:1 or 40:1.

For simplicity, reference will be made to components (or “parts”) of the semiconductor device 200 illustrated in FIG. 2 while referring to FIGS. 3-5A and 5C-7. For clarity of the illustrations provided, not all of the reference numerals of the parts of the semiconductor device 200 are shown in FIGS. 3-5A and 5C-7.

Referring to FIG. 1, 2-5A, and 50-7, in one or more embodiments, the method 100 begins with optional operation 105 to pre-treat the substrate surface 202. The pre-treatment at operation 105 can be any suitable pre-treatment known to the skilled artisan. Suitable pre-treatments include, but are not limited to, pre-heating, cleaning, soaking, native oxide removal, or deposition of a contact layer or capping layer.

The method 100 includes cycle 110. The cycle 110 includes a series of operations which are each performed in sequence and may be repeated. Some of the operations are optional within each cycle. A given optional operation, which is denoted by the dashed boxes, may be performed during each cycle, periodically (every other, every fifth, or every hundredth cycle), or as-needed based on predetermined parameters, or even not at all.

Referring to FIGS. 1 and 3, the cycle 110 begins with operation 112. At operation 112, a first metal layer 240 is deposited on the substrate surface 202. The first metal layer 240 has a bottom thickness on the bottom 216, a top thickness on the top surface 205, and a sidewall thickness on the sidewall 214.

The first metal layer 240 may be deposited by any suitable method. In one or more embodiments, the first metal layer 240 may be deposited by physical vapor deposition (PVD), spin-on, or other insulating layer deposition techniques. In one or more embodiments, the first metal layer 240 is deposited by PVD. In one or more embodiments, such as FIG. 3, the sidewall thickness is less than the top thickness and the bottom thickness. In one or more embodiments, the top thickness is greater than the bottom thickness.

The first metal layer 240 may comprise any suitable material known to the skilled artisan. In one or more embodiments, the first metal layer 240 comprises one or more of tungsten (W), molybdenum (Mo), titanium (Ti), cobalt (Co), ruthenium (Ru), platinum (Pt), nickel (Ni), zirconium (Zr), hafnium (Hf), or copper (Cu). In some embodiments, the first metal layer 240 reacts with the substrate surface 202 to form a metal silicide. In one or more embodiments, the metal silicide formed by the reaction of the first metal layer 240 and the substrate surface 202 comprises one or more of titanium silicide (TiSiₓ), molybdenum silicide (MoSiₓ), cobalt silicide (CoSiₓ), nickel silicide (NiSiₓ), zirconium silicide (ZrSiₓ), hafnium silicide (HfSiₓ), tungsten silicide (WSiₓ), ruthenium silicide (RuSiₓ), or tantalum silicide (TaSiₓ).

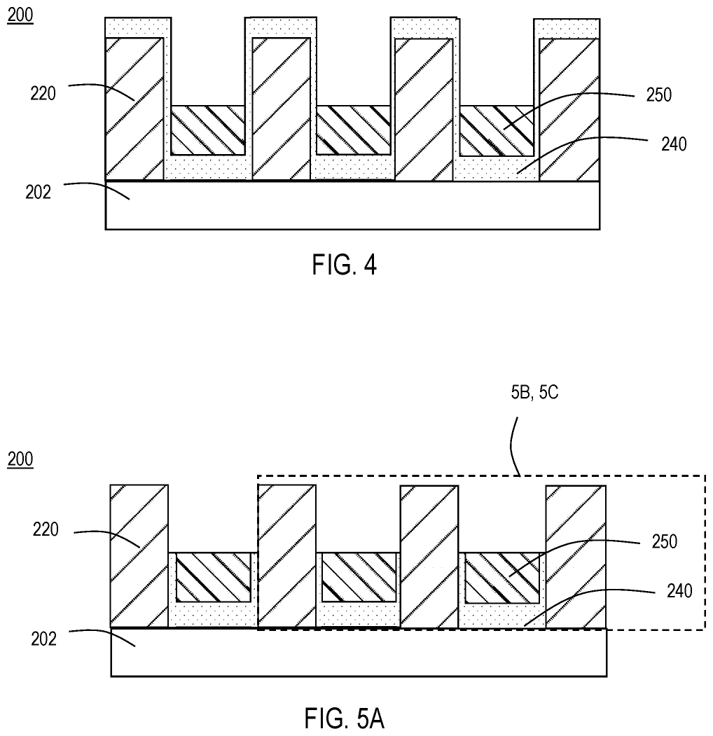

Referring to FIGS. 1 and 4, at operation 114, a flowable oligomer film 250 is formed on the first metal layer 240 within the feature 210. The oligomer film 250 has an oligomer thickness (a height) that is less than or equal to the feature depth 272. Stated differently, as a flowable film (described below), the oligomer film 250 is contained entirely with the feature 210 and is not present on the field (e.g., the top surface 205). In one or more embodiments, the oligomer film 250 has a height in a range of about 1 nm to about 20 nm, such as, for example, in a range of about 2 nm to about 5 nm. In some embodiments, the height of the oligomer film 250 is in a range of from 1% to 99%, or in a range of from 1% to 80%, or in a range of from 2% to 20% of the depth 272 of the at least one feature 210.

In the disclosed methods, processing parameters and reactants may be selected to limit conformality of deposited materials, which may allow the deposited material to better fill features 210 on the substrate surface 202. A flowable material is one which, under the proper conditions, will flow by gravity to the low point of the substrate surface 202 and/or by capillary action to narrow critical dimension (CD) spaces of trenches or other features.

The monomer is the basic unit used to form an oligomer (e.g., the oligomer film 250). The monomer dictates the properties of the oligomer film. Some monomers are stiff monomers, which can lead to oligomer films with higher glass transition temperature (T_{g}). Oligomer films prepared using stiff/inflexible monomers result in oligomer films with lower packing density and a rough surface.

Oligomers used to protect a surface in a feature, such as a trench or a via, as described herein, require surface smoothness. One or more embodiments use flexible monomers to form oligomer films 250 suitable for protecting the bottom 216 of the feature 210.

In some embodiments, forming the oligomer film 250 comprises exposing the substrate surface 202 to one or more monomers. It has been advantageously found that the disclosed flexible monomers used for producing the oligomer film 250 are capable of forming oligomers in a higher percentage during oligomerization compared to stiff monomers.

In one or more embodiments, the monomers form an oligomer film 250 that is continuous. As used herein, the term “continuous” refers to a layer and/or film that covers an entire exposed surface without gaps or bare spots that reveal material underlying the deposited layer and/or film. A continuous layer and/or film may have gaps or bare spots with a surface area less than about 15% or less than about 10% of the total surface area of the layer and/or film. It will be appreciated that the oligomer film 250, such as a continuous oligomer film, covers and protects the bottom 216 of the feature 210.

Flexible monomers provide a smooth surface in the feature 210 with easy packing and packing density. Flexible monomers also reduce oligomer residue on the field area (e.g., the top surface 205) due to the oligomers' volatility and flowability into the feature 210. The oligomer films formed from flexible monomers, as used herein, have flowable capability to move into features 210 when formed on the field area (e.g., the top surface 205). The oligomer films 250 also have enough molecular weight to remain within the features 210 at vacuum pressures.

By this improvement, any residue of the oligomer film 250 on the field (e.g., top surface 205) and on the sidewall 214 is eliminated, enhancing process efficiency. In one or more embodiments, the semiconductor device quality is improved when there is substantially no residue or no residue on the field (e.g., top surface 205) and sidewall 214 area.

In one or more embodiments, oligomers formed with flexible monomers have properties of lower T_{g}. In one or more embodiments, an oligomer is formed having a T_{g} below the deposition temperature of the oligomer process. Such oligomers fold much more easily than oligomers formed from stiff monomers in features having small critical dimensions (CD). In order to control the “flowability” of the resulting oligomer film 250, it has been found that it is necessary to control the size of the resulting oligomers.

In one or more embodiments, the monomers comprise, consist essentially of, or consist of a monomer with a single functional group. Those skilled in the art may recognize this as a “monofunctional monomer” or an “A” monomer.

In one or more embodiments, the monomers comprise, consist essentially of, or consist of a monomer with two functional groups. In this way, at least one functional group of the monomer will react with the other functional group of a different monomer. In one or more embodiments, the monomer with two functional groups is capped by two “A” monomers. The monomer with two functional groups that is capped by two “A” monomers includes different functional groups than the functional group of the “A” monomers. Those skilled in the art may recognize the monomer with two functional groups that is capped by two “A” monomers and includes different functional groups than the functional group of the “A” monomers as a “bifunctional monomer” or a “B” monomer. Stated differently, in some embodiments, the “B” monomer is capped by two

“A” monomers and includes different functional groups than the functional group of the “A” monomers.

Those skilled in the art may recognize a monomer with two functional groups which has different functional groups than the functional groups of the “B” monomers as a “bifunctional monomer” or a “C” monomer. Accordingly, the skilled artisan will appreciate that each of the “B” monomers and the “C” monomers are bifunctional monomers, that the “B” monomers have different functional groups than the “A” monomers, and that the “C” monomers have different functional groups than the “B” monomers.

In some embodiments, the oligomer film 250 is formed from two different monomers, where at least one of the two different monomers is a monofunctional monomer (e.g., the “A” monomer). In some embodiments, the oligomer film 250 is formed from “A” monomers and “B” monomers. In some embodiments, the oligomer film 250 is formed from “A” monomers and “C” monomers. In some embodiments, the oligomer film 250 is formed from “B” monomers and “C” monomers. In some embodiments, the oligomer film 250 is formed from “A” monomers, “B” monomers, and “C” monomers.

In some embodiments, at least one of the monomers includes a methacrylate group, a styrene group, an amine group, a ketone group, a benzyl alcohol group, a benzyl chloride group, or an aldehyde group. In some embodiments, the “A” monomer includes a methacrylate group, a styrene group, an amine group, a ketone group, a benzyl alcohol group, a benzyl chloride group, or an aldehyde group. In some embodiments, the “A” monomer includes an aldehyde group.

In some embodiments, the “B” monomer and/or the “C” monomer includes a methacrylate group, a styrene group, an amine group, a ketone group, a benzyl alcohol group, a benzyl chloride group, or an aldehyde group.

In some embodiments, at least one of the monomers includes amines with bifunctional groups, aldehydes with bifunctional groups, ketones with bifunctional groups, and alcohols with bifunctional groups. In some embodiments, the “B” monomer and/or the “C” monomer includes amines with bifunctional groups, aldehydes with bifunctional groups, ketones with bifunctional groups, or alcohols with bifunctional groups.

In some embodiments, the “B” monomer and/or the “C” monomer includes two amines with bifunctional groups, two aldehydes with bifunctional groups, two ketones with bifunctional groups, and two alcohols with bifunctional groups.

In some embodiments, the amines have a formula of H₂N—(CHₓ)ₙ—NH₂, where n is an integer in a range of from 1 to 20 and x is 1 or 2. In some embodiments, the aldehydes have a formula of OHC—(CHₓ)ₘ—CHO, where m is an integer in a range of from 2 to 20 and x is 1 or 2. In some embodiments, the ketones have a formula of ROC—(CHₓ)_{q}—COR, where q is an integer in a range of from 2 to 20, x is 1 or 2, and R is an alkyl group. In some embodiments, the alcohols have a formula of HOC—(CHₓ)ᵣ—COH, where q is an integer in a range of from 2 to 20 and x is 1 or 2.

In some embodiments, the amines, the aldehydes, the ketones, and the alcohols comprise carbon atoms. In some embodiments, the monomers described herein may be linear, branched, cyclic, saturated, or unsaturated. The monomers described herein do not contain groups which are reactive in the chemical oligomerization process described herein.

In specific embodiments, at least one of the monomers includes one or more of the following compounds:

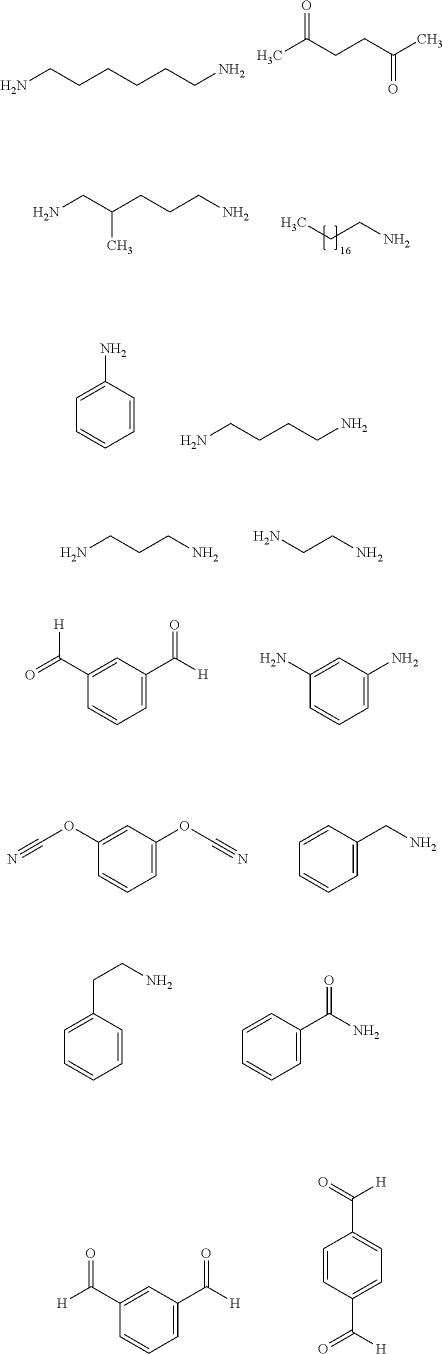

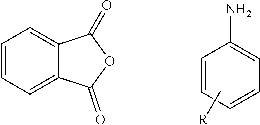

where R is an alkyl group including in a range of from 1 to 8 carbons, and the alkyl group is linear, branched, cyclic, saturated, or unsaturated, such as CₙHₙ₊₁.

In specific embodiments, the “A” monomer includes an aldehyde group, the “B” monomer includes two amines with bifunctional groups, and the “C” monomer includes two aldehydes with bifunctional groups.

It has been found that the controlling one or more parameters including purge time and temperature to control local monomer concentration allows the dimer, trimer, tetramer, and the like, to be bonded intramolecularly.

It has been advantageously found that forming oligomer films can improve uniformity in oligomer fill height in features having varied critical dimensions (CD). It has also been advantageously found that purge time can be reduced significantly when forming the oligomer film 250, even to zero seconds in some cases. Therefore, when the purge time is reduced or at zero seconds, for example, the oligomer film 250 is deposited by a CVD-type process. In this way, the features 210 are exposed to the monomers in a similar concentration and forms oligomers in a similar concentration in features having varying CD to achieve an oligomer film height that is the same or substantially the same.

The oligomer film 250 formation depends on its local concentration of monomers. It has been found that during the purge and pumping stage, the “B” monomer concentration is greatly reduced, especially on the field 205 and sidewall areas 214. In this case, when “A” monomers come in, the “A” monomers and “B” monomers only form oligomers on the field 205 and sidewall areas 214 with very low concentration of “B” monomers. Due to pumping and purge efficiency difference between the field 205 and sidewall areas 214, and bottom 216 of the feature 210, the “B” monomer concentration in the bottom 216 of the feature 210 is higher compared with the concentration on the field 205 and sidewall areas 214. Since the “B” monomer concentration is higher at the bottom 216 of the feature 210, the “B” monomers form higher molecular number oligomer with incoming “A” monomers.

In some embodiments, the oligomer film 250 is formed from two different monomers. In some embodiments, the oligomer film 250 is formed from two different monomers, where at least one of the two different monomers is a monofunctional monomer (an “A” monomer). In some embodiments, the oligomer film 250 is formed from two “A” monomers that are capped by one “B” monomer. For example, in one or more embodiments, the two “A” monomers that are capped by one “B” monomer represent an A-B-A trimer configuration. Those skilled in the art may recognize the A-B-A trimer configuration as an “A-B-A-capped oligomer.”

In one or more embodiments, the oligomer film 250 comprising the A-B-A-capped oligomer is formed by a sequential process comprising a pulse of a “B” monomer in a range of from 0.2 seconds to 4 seconds, purging the substrate surface 202 of the “B” monomer in a range of from 0.1 seconds to 10 seconds, a pulse of an “A” monomer in a range of from 0.2 seconds to 4 seconds, and purging the substrate surface 202 of the “A” monomer in a range of from 0.1 seconds to 10 seconds. This sequential process may be repeated any suitable number of times to deposit the oligomer film 250 to a predetermined thickness.

In one or more embodiments, the oligomer film 250 comprising the A-B-A-capped oligomer is formed by a pulsed CVD process comprising co-flowing an “A” monomer and a “B” monomer in a range of from 0.5 seconds to 2 seconds and purging the substrate surface 202 of any unreacted “A” monomer, “B” monomer, or byproducts thereof in a range of from 0.1 seconds to 10 seconds. This pulsed CVD process may be repeated any suitable number of times to deposit the oligomer film 250 to a predetermined thickness.

In some embodiments, the oligomer film 250 is formed from three different monomers. In some embodiments, the oligomer film 250 is formed two “A” monomers that are capped by two “B” monomers, where the two “A” monomers that are capped by the two “B” monomers are linked together by a “C” monomer. For example, in one or more embodiments, the two “A” monomers that are capped by two “B” monomers, which are linked together by the “C” monomer represents an A-B-C-B-A oligomer configuration. Those skilled in the art may also recognize the A-B-C-B-A oligomer configuration as an “A-B-C-B-A-capped oligomer.”

In one or more embodiments, the oligomer film 250 comprising the A-B-C-B-A-capped oligomer is formed by a sequential process comprising a first pulse of a “B” monomer in a range of from 0.2 seconds to 4 seconds, purging the substrate surface 202 of the “B” monomer in a range of from 0.1 seconds to 10 seconds, a pulse of an “C” monomer in a range of from 0.2 seconds to 4 seconds, purging the substrate surface 202 of the “C” monomer in a range of from 0.1 seconds to 10 seconds, a second pulse of the “B” monomer in a range of from 0.2 seconds to 4 seconds, purging the substrate surface 202 of the “B” monomer in a range of from 0.1 seconds to 10 seconds, a pulse of an “A” monomer in a range of from 0.5 seconds to 4 seconds, and purging the substrate surface of the “A” monomer in a range of from 0.1 seconds to 10 seconds. This sequential process may be repeated any suitable number of times to deposit the oligomer film 250 to a predetermined thickness.

In some embodiments, the oligomer film 250 is formed from two different bifunctional monomers. In some embodiments, the oligomer film 250 is formed from “C” monomers that are capped by “B” monomers, and the “B” monomers and the “C” monomers collectively form a ring shape. For example, in one or more embodiments, the ring shape represents one or more of a C-B-C-B oligomer configuration, a C-B-C-B-C-B oligomer configuration, or a C-B-C-B-C-B-C-B oligomer configuration, as examples. Those skilled in the art may recognize each of the C-B-C-B oligomer configuration, the C-B-C-B-C-B oligomer configuration, or the C-B-C-B-C-B-C-B oligomer configuration as “ring termination oligomers.”

Accordingly, in one or more embodiments, the oligomer film 250 is formed at a temperature in a range of 0° C. to 400° C. In one or more embodiments, the oligomer film 250 is formed at a temperature greater than or equal to about 0° C., greater than or equal to about 30° C., greater than or equal to about 50° C., greater than or equal to about 100° C., greater than or equal to about 200° C., or greater than or equal to about 300° C. In one or more embodiments, the oligomer film 250 is formed at a temperature less than or equal to about 400° C., less than or equal to about 300° C., less than or equal to about 200° C., less than or equal to about 100° C., less than or equal to about 50° C., or less than or equal to about 30° C.

Further, other process parameters may be controlled during the formation of the oligomer film 250. Examples of parameters which may be controlled include, but are not limited to processing chamber pressure, monomer selections, the use of an inert diluent or carrier gas, partial pressures of monomers, pulse sequence of monomers, and pause periods to permit flow of the oligomer material.

Referring to FIGS. 1, 5A, and 5C, at operation 116, at least a portion of the first metal layer 240 is selectively removed. FIG. 5C illustrates an exploded view of the semiconductor substrate surface 202 in cross-section.

In particular, FIG. 5C illustrates the oligomer film 250 that has a height which is substantially the same or the same in features with varying critical dimensions (CD). In one or more embodiments, FIG. 5C illustrates a first feature having a first critical dimension (CD) 275 and a second feature having a second CD 285. In one or more illustrated embodiments, the second CD 285 is greater than the first CD 275. Advantageously, the oligomer film 250 has a height which is substantially the same or the same in the first feature and the second feature where the second CD 285 is greater than the first CD 275.

As used in this regard, a height which is “substantially the same” means that the height of the oligomer film 250 differs by less than or equal to 5%, including less than or equal to 4%, less than or equal to 3%, less than or equal to 2%, less than or equal to 1%, less than or equal to 0.5%, and less than or equal to 0.1% in the first feature and the second feature where the second CD 285 is different than the first CD 275.

In one or more embodiments, the oligomer film 250 has a height which is in a range of about 1 nm to about 20 nm, such as, for example, in a range of about 2 nm to about 5 nm, in each of the first feature and the second feature where the second CD 285 is greater than the first CD 275, and the height of the oligomer film 250 is substantially the same or the same.

FIG. 5B illustrates an exploded view of a semiconductor substrate 20 in cross-section according to the prior art. In particular, FIG. 5B illustrates a first feature having a first critical dimension (CD) 60 and a second feature having a second CD 70. A first metal layer 24 is deposited on at least a portion of the first feature and the second feature, e.g., the bottom of the first feature and the second feature. A polymer film 25 is deposited on the first metal layer 24 on the bottom of the first feature and the second feature. In the illustrated embodiment of FIG. 5B, the height of the polymer film 25 varies with varying CD. In the illustrated embodiment of FIG. 5B, the height of the polymer film 25 is greater in the first feature having the first CD 60 than the height of the same polymer film in the second feature having the second CD 70. Accordingly, the effectiveness of depositing the polymer film 25 with a height that is the same or substantially the same is dependent on the CD of the features, and cannot be achieved in embodiments such as FIG. 5B where the second CD 70 is greater than the first CD 60.

For comparative purposes, the first CD 60 and the second CD 70 of the prior art semiconductor substrate 20 are the same as the first CD 275 and the second CD 285 of the semiconductor device 200 formed by the disclosed methods (e.g., method 100). Advantageously, the oligomer film 250 has a height which is substantially the same or the same in the first feature and the second feature where the second CD 285 is greater than the first CD 275, and the effectiveness of depositing the oligomer film 250 is not dependent on the CD of the features.

Referring again to FIGS. 1, 5A, and 5C, the first metal layer 240 is removed from the top surface 205 without substantially affecting any material beneath the oligomer film 250. As used in this regard, a process which does not “substantially affect” material layers does not cause any decrease in volume, thickness, or composition. One skilled in the art will recognize that the oligomer film 250 is acting as an etch stop layer during the removal of a portion of the first metal layer 240.

In some embodiments, operation 116 also removes a portion of the first metal layer 240 from the sidewall 214. In one or more embodiments, the first metal layer 240 which is present on sidewall 214 below the upper surface of the oligomer film 250 may remain intact without being removed.

In some embodiments, a portion of the first metal layer 240 is selectively removed by exposing the substrate surface 202 of the semiconductor device 200 to NF₃ radicals. In some embodiments, a portion of the first metal layer 240 is selectively removed by exposing the substrate surface 202 to a fluorine-based plasma or a chlorine-based plasma. In one or more embodiments, a portion of the first metal layer 240 is selectively removed at a temperature in a range of 80° C. to 150° C.

In one or more embodiments, a portion of the first metal layer 240 is selectively removed by a sequence of oxidizing the metal layer 240 and exposing the oxidized material to a metal halide to etch the oxidized material. In one or more embodiments, when the metal material comprises tungsten, and the metal halide comprises WCl₅.

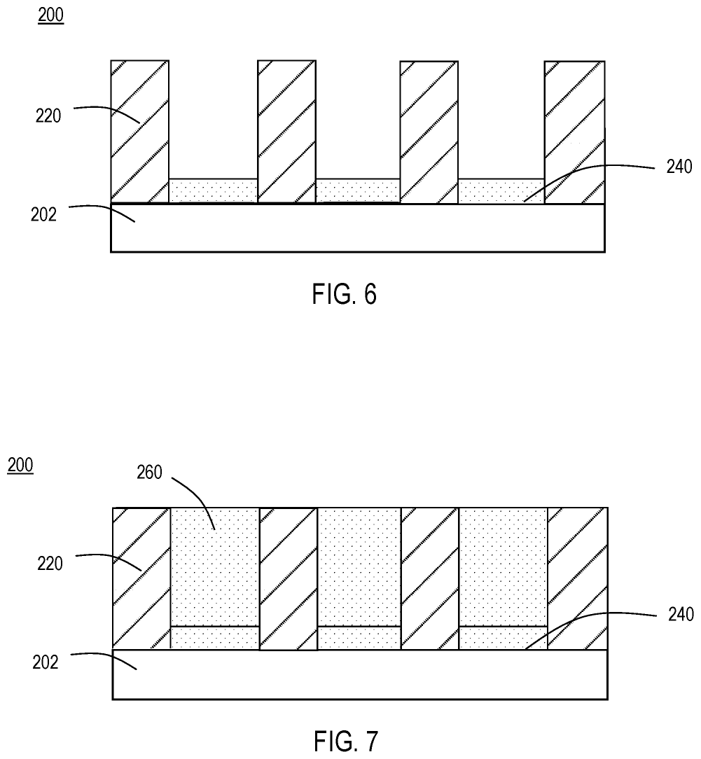

Referring to FIGS. 1 and 6, at optional operation 118, the oligomer film 250 is removed to expose the first metal layer 240 beneath the oligomer film 250. In one or more illustrated embodiments, the removal of the oligomer film 250 is complete and leaves substantially no or no residue.

In some embodiments, the oligomer film 250 is removed by exposing the substrate surface 202 of the semiconductor device 200 to one or more of a thermal vacuum method or a hydrogen (H₂) plasma treatment. In some embodiments, the oligomer film 250 is removed by exposing the substrate surface 202 of the semiconductor device 200 to a hydrogen (H₂) plasma treatment. In one or more embodiments, the oligomer film 250 is removed by exposure to a thermal O₂ environment at an elevated temperature.

In one or more embodiments, after removing the first metal layer 240 from the top surface 205 and sidewall 214, the oligomer film 250 can be removed thermally by heating it to 350° C. to 500° C. under vacuum. In other embodiments, after removing the first metal layer 240 from the top surface 205 and sidewall 214, the oligomer film 250 may also be removed by hydrogen (H₂) plasma at temperature in a range of from 100° C. to 300° C. for a time period in a range of from 2 seconds to 30 seconds.

At optional operation 119, unillustrated, the substrate surface 202 may be optionally cleaned. The cleaning process can be any suitable process which cleans the surface of the first metal layer 240. In some embodiments, the cleaning process does not oxidize the metal surface.

In one or more embodiments, at the end of cycle 110, the surface of the first metal layer 240 does not contain any contaminants or residues of the oligomer film 250. Specifically, in one or more embodiments, there are no carbon or oxygen residues on the surface of the first metal layer 240. In one or more embodiments, when the method 100 includes repeated cycles 110 (see below), there are no contaminants or residues between amounts of the first metal layer 240 deposited in subsequent cycles. In one or more embodiments, when the method 100 includes the deposition of a second metal layer 260 (described below), there are no contaminants or residues between the first metal layer 240 and the second metal layer 260.

In one or more embodiments, the surface of the first metal layer 240 does not contain any contaminants or residues of the oligomer film 250 as a result of the removal process at operation 118 which leaves no residues or contaminants. In one or more embodiments, the surface of the first metal layer 240 does not contain any contaminants or residues of the oligomer film 250 as a result of the clean process at operation 119. In one or more embodiments, the surface of the first metal layer 240 does not contain any contaminants or residues of the oligomer film 250 as a result of a combination of operations 118 and operation 119. In one or more embodiments, the monomers are selected so as not to contain any oxygen atoms which may oxidize the surface of the first metal layer 240 during removal of the oligomer film 250.

The method 100 continues to decision point 120. At decision point 120, the substrate surface 202 is evaluated to determine whether or not the first metal layer 240 has reached a predetermined thickness or a predetermined number of cycles 110 have been performed. If the conditions are met, the method 100 continues to operation 130. If the conditions are not met, the method 100 returns to the beginning of cycle 110 with operation 112. In those embodiments in which the cycle 110 is repeated to form additional material, those skilled in the art will appreciate that operation 112 is often performed to deposit the requisite additional metal material. In one or more embodiments, the predetermined thickness is in a range of about 2 nm to about 10 nm.

At operation 130, unillustrated, the first metal layer 240 may be optionally etched. In one or more embodiments, the first metal layer 240 is etched to remove the portions of the first metal layer 240 which extend up the sidewall 214. When etched, the first metal layer 240 is also thinned on the bottom 216 of the feature 210. Accordingly, one skilled in the art will recognize that the first metal layer 240 may be deposited to a greater bottom thickness than desired in a final product to provide for sacrificial material which will be removed when etching the first metal layer 240 from the sidewall 214.

Referring to FIGS. 1 and 7, at optional operation 140, a second metal layer 260 is selectively deposited on the first metal layer 240. The deposition process is selective to the surface of the first metal layer 240 over other substrate surface materials (e.g., material 220). The selective deposition process provides a gap fill material comprising the second metal layer 260 which is formed in a bottom-up fashion without lateral deposition from the sidewall 214. In one or more embodiments, the second metal layer 260 is deposited without forming any voids or seams within the second metal layer 260.

In one or more embodiments, the first metal layer 240 and the second metal layer 260 comprise the same metal. In one or more embodiments, the metal material 240 and the second metal layer 260 comprise different metals. In some embodiments, the first metal layer 240 comprises, consists essentially of, or consists of one or more of tungsten (W), molybdenum (Mo), ruthenium (Ru), cobalt (Co), nickel (Ni), titanium (Ti), and tantalum (Ta). In some embodiments, the second metal layer 260 comprises, consists essentially of, or consists of one or more of tungsten (W), molybdenum (Mo), ruthenium (Ru), cobalt (Co), nickel (Ni), titanium (Ti), or tantalum (Ta).

The method 100 may end after operation 140 or it may continue with optional post processing at optional operation 150. The optional post-processing operation 150 can be, for example, a process to modify layer/film properties (e.g., annealing or plasma treatment), a further film deposition process (e.g., additional ALD or CVD processes) to grow additional films, or a further etch process to form a desired predetermined device architecture. In one or more embodiments, the optional post-processing operation 150 can be a process that modifies a property of one or more of the first metal layer 240 or the second metal layer 260. In one or more embodiments, the optional post-processing operation 150 comprises annealing the semiconductor device 200. In one or more embodiments, annealing is performed at a temperature greater than or equal to about 300° C., greater than or equal to about 400° C., greater than or equal to about 500° C., greater than or equal to about 600° C., greater than or equal to about 700° C., greater than or equal to about 800° C., greater than or equal to about 900° C. or greater than or equal to about 1000° C. The annealing environment of one or more embodiments comprises one or more of an inert gas (e.g., molecular nitrogen (N₂), argon (Ar)) or a reducing gas (e.g., molecular hydrogen (H₂) or ammonia (NH₃) or an oxidant, such as, but not limited to, oxygen (O₂), ozone (O₃), or peroxides. Annealing can be performed for any suitable length of time. In one or more embodiments, the substrate is annealed for a predetermined time in the range of about 15 seconds to about 90 minutes, or in the range of about 1 minute to about 60 minutes.

In one or more embodiments, the method 100 comprises operation 105, operation 112, operation 114, operation 116, operation 118, operation 119, decision point 120, operation 130, operation 140, and operation 150. In one or more embodiments, the method 100 consists essentially of operation 105, operation 112, operation 114, operation 116, operation 118, operation 119, decision point 120, operation 130, operation 140, and operation 150. In one or more embodiments, the method 100 consists of operation 105, operation 112, operation 114, operation 116, operation 118, operation 119, decision point 120, operation 130, operation 140, and operation 150.

In one or more embodiments, the method 100 comprises operation 112, operation 114, operation 116, operation 118, decision point 120, and operation 140. In one or more embodiments, the method 100 consists essentially of operation 112, operation 114, operation 116, operation 118, decision point 120, and operation 140. In one or more embodiments, the method 100 consists of operation 112, operation 114, operation 116, operation 118, decision point 120, and operation 140.

FIG. 8 illustrates a schematic top-view diagram of an example of a multi-chamber processing system 400 according to embodiments of the present disclosure. The processing system 400 generally includes a factory interface 402, load lock chambers 404, 406, transfer chambers 408, 410 with respective transfer robots 412, 414, holding chambers 416, 418, and processing chambers 420, 422, 424, 426, 428, 430. As detailed herein, wafers in the processing system 400 can be processed in and transferred between the various chambers without exposing the wafers to an ambient environment exterior to the processing system 400 (e.g., an atmospheric ambient environment such as may be present in a fab). For example, the wafers can be processed in and transferred between the various chambers in a low pressure (e.g., less than or equal to about 300 Torr) or vacuum environment without breaking the low pressure or vacuum environment between various processes performed on the wafers in the processing system 400. Accordingly, the processing system 400 may provide an integrated solution for some processing of wafers.

The skilled artisan will appreciate that commercially available processing chambers and/or processing systems may be suitably modified in accordance with the teachings provided herein.

In the illustrated example of FIG. 8, the factory interface 402 includes a docking station 440 and factory interface robots 442 to facilitate transfer of wafers. The docking station 440 is configured to accept one or more front opening unified pods (FOUPs) 444. In some examples, each factory interface robot 442 generally comprises a blade 448 disposed on one end of the respective factory interface robot 442 configured to transfer the wafers from the factory interface 402 to the load lock chambers 404, 406.

The load lock chambers 404, 406 have respective ports 450, 452 coupled to the factory interface 402 and respective ports 454, 456 coupled to the transfer chamber 408. The transfer chamber 408 further has respective ports 458, 460 coupled to the holding chambers 416, 418 and respective ports 462, 464 coupled to processing chambers 420, 422. Similarly, the transfer chamber 410 has respective ports 466, 468 coupled to the holding chambers 416, 418 and respective ports 470, 472, 474, 476 coupled to processing chambers 424, 426, 428, 430. The ports 454, 456, 458, 460, 462, 464, 466, 468, 470, 472, 474, 476 can be, for example, slit valve openings with slit valves for passing wafers therethrough by the transfer robots 412, 414 and for providing a seal between respective chambers to prevent a gas from passing between the respective chambers. Generally, any port is open for transferring a wafer therethrough. Otherwise, the port is closed.

The load lock chambers 404, 406, transfer chambers 408, 410, holding chambers 416, 418, and processing chambers 420, 422, 424, 426, 428, 430 may be fluidly coupled to a gas and pressure control system (not specifically illustrated). The gas and pressure control system can include one or more gas pumps (e.g., turbo pumps, cryo-pumps, roughing pumps), gas sources, various valves, and conduits fluidly coupled to the various chambers. In operation, a factory interface robot 442 transfers a wafer from a FOUP 444 through a port 450 or 452 to a load lock chamber 404 or 406. The gas and pressure control system then pumps down the load lock chamber 404 or 406. The gas and pressure control system further maintains the transfer chambers 408, 410 and holding chambers 416, 418 with an interior low pressure or vacuum environment (which may include an inert gas). Hence, the pumping down of the load lock chamber 404 or 406 facilitates passing the wafer between, for example, the atmospheric environment of the factory interface 402 and the low pressure or vacuum environment of the transfer chamber 408.

With the wafer in the load lock chamber 404 or 406 that has been pumped down, the transfer robot 412 transfers the wafer from the load lock chamber 404 or 406 into the transfer chamber 408 through the port 454 or 456. The transfer robot 412 is then capable of transferring the wafer to and/or between any of the processing chambers 420, 422 through the respective ports 462, 464 for processing and the holding chambers 416, 418 through the respective ports 458, 460 for holding to await further transfer. Similarly, the transfer robot 414 is capable of accessing the wafer in the holding chamber 416 or 418 through the port 466 or 468 and is capable of transferring the wafer to and/or between any of the processing chambers 424, 426, 428, 430 through the respective ports 470, 472, 474, 476 for processing and the holding chambers 416, 418 through the respective ports 466, 468 for holding to await further transfer. The transfer and holding of the wafer within and among the various chambers can be in the low pressure or vacuum environment provided by the gas and pressure control system.

The processing chambers 420, 422, 424, 426, 428, 430 can be any appropriate chamber for processing a wafer. In some embodiments, the processing chamber 420 can be capable of performing an annealing process, the processing chamber 422 can be capable of performing a cleaning process, and the processing chambers 424, 426, 428, 430 can be capable of performing epitaxial growth processes. In some examples, the processing chamber 422 can be capable of performing a cleaning process, the processing chamber 420 can be capable of performing an etch process, and the processing chambers 424, 426, 428, 430 can be capable of performing respective epitaxial growth processes.

A system controller 490 is coupled to the processing system 400 for controlling the processing system 400 or components thereof. For example, the system controller 490 may control the operation of the processing system 400 using a direct control of the chambers 404, 406, 408, 416, 418, 410, 420, 422, 424, 426, 428, 430 of the processing system 400 or by controlling controllers associated with the chambers 404, 406, 408, 416, 418, 410, 420, 422, 424, 426, 428, 430. In operation, the system controller 490 enables data collection and feedback from the respective chambers to coordinate performance of the processing system 400.

The system controller 490 generally includes a central processing unit (CPU) 492, memory 494, and support circuits 496. The CPU 492 may be one of any form of a general-purpose processor that can be used in an industrial setting. The memory 494, or non-transitory computer-readable medium, is accessible by the CPU 492 and may be one or more of memory such as random-access memory (RAM), read only memory (ROM), floppy disk, hard disk, or any other form of digital storage, local or remote. The support circuits 496 are coupled to the CPU 492 and may comprise cache, clock circuits, input/output subsystems, power supplies, and the like. The various methods disclosed herein may generally be implemented under the control of the CPU 492 by the CPU 492 executing computer instruction code stored in the memory 494 (or in memory of a particular processing chamber) as, for example, a software routine. When the computer instruction code is executed by the CPU 492, the CPU 492 controls the chambers to perform processes in accordance with the various methods.

Other processing systems can be in other configurations. For example, more or fewer processing chambers may be coupled to a transfer apparatus. In the illustrated example, the transfer apparatus includes the transfer chambers 408, 410 and the holding chambers 416, 418. In other examples, more or fewer transfer chambers (e.g., one transfer chamber) and/or more or fewer holding chambers (e.g., no holding chambers) may be implemented as a transfer apparatus in a processing system.

As used herein, the term “in situ” refers to processes that are all performed in the same processing chamber or within different processing chambers that are connected as part of an integrated processing system, such that each of the processes are performed without an intervening vacuum break. As used herein, the term “ex situ” refers to processes that are performed in at least two different processing chambers such that one or more of the processes are performed with an intervening vacuum break. One or more operations of method 100 may be performed in situ. One or more operations of method 100 may be performed ex situ.

Processes may generally be stored in the memory of the system controller 490 as a software routine that, when executed by the processor, causes the processing chamber to perform processes of the present disclosure. The software routine may also be stored and/or executed by a second processor (not shown) that is remotely located from the hardware being controlled by the processor. Some or all of the methods of the present disclosure may also be performed in hardware. As such, the process may be implemented in software and executed using a computer system, in hardware as, e.g., an application specific integrated circuit or other type of hardware implementation, or as a combination of software and hardware. The software routine, when executed by the processor, transforms the general-purpose computer into a specific purpose computer (controller) that controls the chamber operation such that the processes are performed.

Embodiments of the disclosure are directed to a non-transitory computer readable medium. In one or more embodiments, the non-transitory computer readable medium includes instructions that, when executed by a controller (e.g., controller 490) of a processing chamber (or processing system 400), causes a processing chamber to perform the operations of any of the methods (e.g., method 100) described herein.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure include modifications and variations that are within the scope of the appended claims and their equivalents.

What is claimed is:

1. A processing method comprising:
exposing a semiconductor substrate surface with at least one feature formed thereon to one or more monomers to form an oligomer film, the at least one feature having at least one opening having a width, at least one sidewall, and a bottom, the at least one feature extending a feature depth from a top surface to the bottom, the oligomer film forming selectively on the bottom and filling a portion of the feature depth.

2. The processing method of claim 1, wherein at least one of the monomers includes a methacrylate group, a styrene group, an amine group, a ketone group, a benzyl alcohol group, a benzyl chloride group, or an aldehyde group.

3. The processing method of claim 1, wherein at least one of the monomers includes amines with bifunctional groups, aldehydes with bifunctional groups, ketones with bifunctional groups, and alcohols with bifunctional groups.

4. The processing method of claim 1, wherein the oligomer film is formed from two different monomers, where at least one of the two different monomers is a monofunctional monomer.

5. The processing method of claim 1, wherein the oligomer film is formed by a chemical vapor deposition (CVD) process or an atomic layer deposition (ALD) process.

6. The processing method of claim 1, wherein the at least one feature includes a first feature and a second feature, the first feature having a first critical dimension (CD) and the second feature having a second CD.

7. The processing method of claim 6, wherein the second CD is greater than the first CD.

8. The processing method of claim 7, wherein the oligomer film fills the feature depth to substantially the same height in each of the first feature and the second feature.

9. The processing method of claim 1, further comprising depositing a first metal layer by physical vapor deposition (PVD) on the top surface, on the at least one sidewall, and on the bottom of the at least one feature prior to forming the oligomer film.

10. The processing method of claim 9, further comprising selectively removing at least a portion of the first metal layer from the top surface of the oligomer film and the at least one sidewall.

11. The processing method of claim 10, further comprising removing the oligomer film to expose the first metal layer on the bottom of the at least one feature.

12. The processing method of claim 9, wherein the first metal layer comprises one or more of tungsten (W), molybdenum (Mo), ruthenium (Ru), cobalt (Co), nickel (Ni), titanium (Ti), and tantalum (Ta).

13. The processing method of claim 12, further comprising selectively depositing a second metal layer on the first metal layer to fill the at least one feature.

14. The processing method of claim 13, wherein the second metal layer comprises one or more of tungsten (W), molybdenum (Mo), ruthenium (Ru), cobalt (Co), nickel (Ni), titanium (Ti), or tantalum (Ta).

15. The processing method of claim 11, wherein removing the oligomer film comprises exposing the semiconductor substrate surface to one or more of a thermal vacuum method or a hydrogen (H₂) plasma treatment.

16. The processing method of claim 15, wherein the oligomer film is removed without substantially affecting any material beneath the oligomer film.

17. A processing method comprising:
exposing a semiconductor substrate surface with a first feature and a second feature formed thereon to one or more monomers to form an oligomer film, each of the first feature and the second feature having at least one opening having a width, at least one sidewall, and a bottom, and extending a feature depth from a top surface to the bottom, the first feature having a first critical dimension (CD) and the second feature having a second CD, the second CD greater than the first CD, and the oligomer film forming selectively on the bottom and filling a portion of the feature depth.

18. The processing method of claim 17, wherein the oligomer film fills the feature depth to substantially the same height in each of the first feature and the second feature.

19. A method of forming a semiconductor device, the method comprising:
depositing a first metal layer on a substrate surface with a first feature and a second feature formed thereon, each of the first feature and the second feature including at least one opening, at least one sidewall, and a bottom, and extending a feature depth from a top surface to the bottom, the first feature having a first critical dimension (CD) and the second feature having a second CD, the second CD greater than the first CD, the first metal layer forming on the top surface, on the at least one sidewall, and on the bottom;
exposing the substrate surface to one or more monomers to form an oligomer film on the first metal layer within the first feature and the second feature, the oligomer film forming on the first metal layer on the bottom and on a portion of the at least one sidewall, the oligomer film filling the feature depth to substantially the same height in each of the first feature and the second feature;
selectively removing the first metal layer from the top surface and from the at least one sidewall;
removing the oligomer film to expose the first metal layer on the bottom of the first feature and the second feature; and
selectively depositing a second metal layer on the first metal layer to fill each of the first feature and the second feature.

20. The method of claim 19, wherein the oligomer film is formed by a chemical vapor deposition (CVD) process or an atomic layer deposition (ALD) process.
